(19) United States
(12) Patent Application Publication
(10) Pub. No.: US 2019/0113744 A1
(43) Pub. Date: Apr. 18, 2019

(54) Electromechanical Oscillatory System

(71) Applicant: Texas Instruments Incorporated, Dallas, TX (US)

(72) Inventor: David Patrick Magee, Allen, TX (US)

(21) Appl. No.: 16/163,309

(22) Filed: Oct. 17, 2018

Related U.S. Application Data
(60) Provisional application No. 62/573,878, filed on Oct. 18, 2017.
(60) Provisional application No. 62/576,512, filed on Oct. 24, 2017.

(51) Int. Cl. G02B 27/00; B08B 7/02; H01L 41/09

(52) U.S. Cl. CPC G02B 27/0006; H01L 41/0973; B08B 7/028

(57) ABSTRACT

An oscillatory system comprises: a target member; a transducer coupled to the target member; and circuitry for applying a voltage to the transducer for imparting a vibrational force to the target member.

### CROSS-REFERENCE TO RELATED APPLICATIONS

This application claims priority to, the benefit of the filing date of, and hereby incorporates herein by reference: U.S. Provisional Patent Application No. 62/573,878, entitled “INTEGRATED LENS CLEANER SYSTEM FOR SELF-CLEANING CAMERAS,” filed Oct. 18, 2017; and U.S. Provisional Patent Application No. 62/576,512, entitled “RESONANCE MATCHING TO IMPROVE THE QUALITY (Q) FACTOR IN ELECTRO-MECHANICAL SYSTEMS,” filed Oct. 24, 2017.

### BACKGROUND

This document relates generally to electromechanical oscillatory systems, and more particularly to an architecture, design and method involving an actuator and a target member resonated by the actuator to oscillate at a target frequency.

Electromechanical oscillatory systems exist in various forms, with one example shown in co-owned U.S. Patent Application Publication No. 2018/0031826, entitled “Ultrasound Lens Structure Cleaner Architecture and Method,” filed Aug. 1, 2016, which is hereby fully incorporated herein by reference. U.S. Patent Application Publication No. 2018/0031826 illustrates and describes a lens structure cleaning system with an actuator (in the form of an ultrasonic transducer) and a target member (in the form of a lens cover), in contact with one another, such as via an adhesive. Electrical signals applied to the actuator/transducer are converted to the physical domain, where the actuator/transducer responsively vibrates based on the applied electrical energy, and such energy is thus transferrable by its physical coupling to the target member/lens cover, causing the latter to likewise vibrate. At selected frequencies, a certain modal response occurs in the target member, which may be one of various vibrational patterns. As a result, the modal response of the target member/lens cover can dislodge debris (e.g., water, contaminants) otherwise located on the lens cover, thereby providing a cleaning function.

### SUMMARY

In one example, a lens structure system comprises: a housing; a plurality of lenses supported by an interior of the housing; a terminal lens coupled to an opening of the housing; a single-segment transducer coupled to the housing and to the terminal lens; a photodetector, positioned to receive light through the plurality of lenses and the terminal lens, for generating image signaling in response to the received light; and circuitry to apply a voltage to the transducer for imparting a vibrational force to the terminal lens.

In another example, an oscillatory system comprises: a target member; a transducer coupled to the target member; and circuitry for applying a voltage to the transducer for imparting a vibrational force to the target member. The target member has a resonant frequency within 10 percent of a predetermined frequency. The transducer has a resonant frequency within 10 percent of the predetermined frequency.

### BRIEF DESCRIPTION OF THE DRAWINGS

FIG. 1A is a cross-sectional view of an example oscillatory system.

FIG. 1B is an exploded view of certain components of the system of FIG. 1A, including a single-segment transducer.

FIG. 1C is an exploded view of certain components of the system of FIG. 1A, including a multi-segment transducer.

FIG. 2 illustrates an example method of designing and constructing a system, such as the system of FIGS. 1A through 1C.

FIG. 3 illustrates an example vehicle V with multiple implementations of the system of FIGS. 1A through 1C.

### DETAILED DESCRIPTION

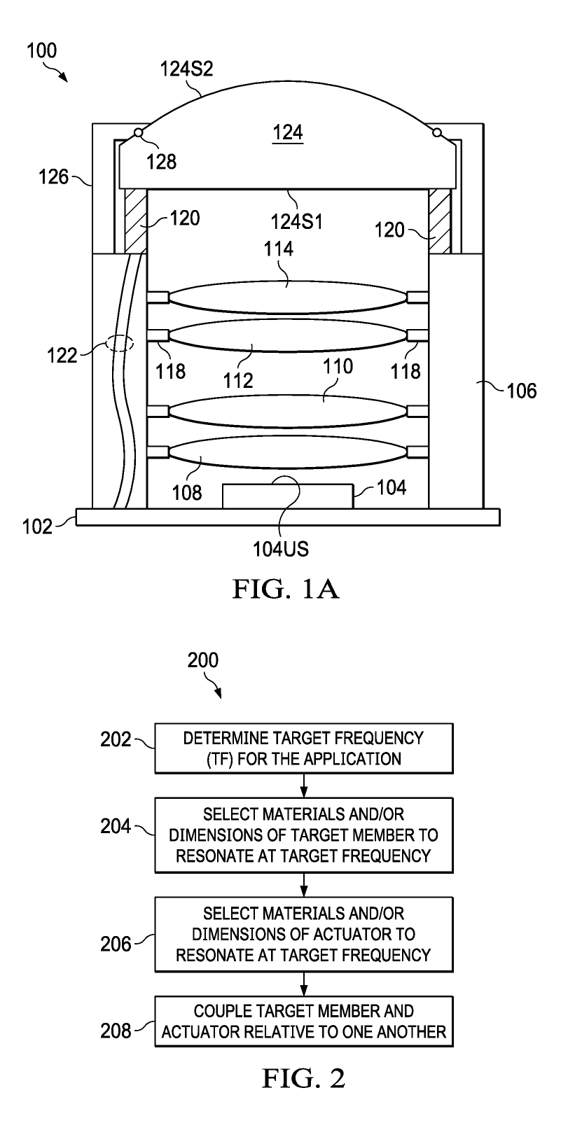

FIG. 1A is a cross-sectional view of an example embodiment electromechanical oscillatory system 100, and FIG. 1B and FIG. 1C are exploded views of alternatives for certain components of system 100 (shown in FIG. 1B as system 100 and in FIG. 1C as system 100′). System 100 facilitates a lens cleaning function. Accordingly, in many environments, part of the exterior of system 100 may become occluded by additional contaminating matter (e.g., dirt, water, other airborne constituents), so that light is partially or fully blocked from an external lens of the system 100. Example embodiments endeavor to reduce or dispel such matter from the exterior surface of that lens. Moreover, various members of system 100 are described below by way of structural relationship, with additional considerations for alternative embodiment dimensions also being described below.

System 100 includes a substrate 102, such as a printed circuit board (PCB) substrate 102, which serves as a structural foundation and also can facilitate electrical connectivity. A photodetector 104 (positioned above substrate 102) is internally located within a lens housing 106. In at least one example, photodetector 104 may be embodied as an integrated circuit die. Lens housing 106 may be cylindrical or at least provide a circular or other appropriately shaped inner cross-section to facilitate the functionality described herein. Photodetector 104 includes sufficient circuitry and the like to receive light at its upper surface 104US and to process such received light into an image signal. Various types of electrical communication may be implemented between photodetector 104 and substrate 102, such as by solder ball, wire or other electrical connectivity. Internal lenses are located within the interior of lens housing 106. The example of FIG. 1A shows four such lenses 108, 110, 112 and 114. Each such lens is coupled (directly or indirectly affixed) to the interior by some retaining apparatus 118, which may be a recess or indent in the inner diameter wall of housing 106, but which FIG. 1A shows as respective coupling members indicated generally at 118.

An actuator 120 (positioned above lens housing 106) is an annular ultrasonic transducer, which may be formed of (or include) a piezoelectric material. In this example, actuator 120 has a cross-sectional shape, such as circular, and is dimensioned to align with housing 106. In the example of FIG. 1B, actuator 120 is a single-segment transducer, which is operable to cause a standing wave pattern in a target member described below. In contrast, the alternative example of FIG.1C shows the actuator 120′ as a multi-segment transducer, which has multiple circular sectors, each having a respective pair of conductors (not separately shown) to apply a voltage to the respective sector, and which is operable to cause either a standing wave pattern or traveling wave patterns in a target member described below. In this example, transducer actuator 120′ has four such segments (or sectors), each consisting of approximately (or slightly less than) 90 degrees of the entire 360 degree circular cross-sectional perimeter of the actuator. Each segment has an outer electrode SOEₓ and an inner electrode SIEₓ, which may be achieved by silk-screening or otherwise attaching a thin conductive material to the respective outer and inner diameters of the piezoelectric material. As shown generally in FIG. 1A, an example embodiment may include electrical connectors/wires 122 connected from substrate 102 to each of the illustrated electrodes. Such conductors are driven by photodetector 104 or a separate driver circuit (not shown) for outputting signals to the conductors. Those signals are therefore applied (and alternated in amplitude, sign and frequency) to excite various vibrational responses in actuator 120 (or 120′).

A terminal lens 124 is positioned above actuator 120 (or 120′), either by partial or full direct physical contact/abutment, and/or also in connection with an interim structure and/or adhesive (not shown). Terminal lens 124 is part of the stack of lenses for system 100. That stack of lenses includes lenses 108, 110, 112, 114 and 124. Terminal lens 124 has: (a) a first surface 124S1 enclosed within, or in fluid communication with, the interior of housing 106; and (b) a second surface 124S2 that is at least partially exposed to exterior ambient air and conditions. In a first embodiment, surface 124S2 is flat or slightly curved to allow exterior light entry into lens 124 at a relatively narrow angle (e.g., 60 degrees to 80 degrees), relative to the center axis through the lenses of system 100. Thus, such light may pass through flat lens 124, and all of lenses 114, 112, 110 and 108, to reach photodetector 104. In a second embodiment, surface 124S2 is convex, thereby shaping lens 124 as a fisheye lens, to allow exterior light entry into lens 124 at a relatively wide angle (e.g., 140 to 180 degrees), relative to the center axis through the lenses of system 100. Thus, such light may pass through fisheye lens 124, and all of lenses 114, 112, 110 and 108, to reach photodetector 104.

Further, a lens retainer member 126 (positioned above or integral with housing 106) retains terminal lens 124 in fixed position relative to the other apparatus of system 100, either directly or in combination with an optional rubber seal (e.g., O-ring) 128. Accordingly, lens retainer member 126 includes a radially-inward extending portion that applies pressure to side 124S2, so as to retain lens 124 in fixed position to an opening in system 100, such as along or proximate the end or an edge of system 100, and so a concave portion of lens 124 may extend beyond an exterior edge of member 126 to increase the wide angle receipt of light.

In an example operation of system 100, photodetector 104 is electrically energized and receives light signals through all of lenses 108, 110, 112, 114 and 124, and converts those light signals to electrical signals. Accordingly, the resultant signals may be communicated to various image processing circuitry (such as processors, controllers, application specific integrated circuits and the like), either on substrate 102 or elsewhere. In another aspect of operation, and more particularly in connection with dispelling debris from the outer surface side 124S2 of lens 124, actuator 120 is excited with various signals from substrate 102 and responds by communicating vibrational forces into the abutted terminal lens 124, so lens 124 is the above-described target member vibrated by actuator 120 (or 120′). Such waves may be communicated in a vibration mode, such as: radial mode at low frequencies (e.g., 44 kHz) along a circumference of the circular cross section of actuator 120; axial mode at relative middle frequencies (e.g., 250 kHz) in a direction of the axis of the cylindrical transducer (i.e., vertical in FIGS. 1A and 1B); and a wall mode at higher frequencies (e.g., 2 MHz) that represent a radial motion of the wall thickness with respect to the outer wall of actuator 120. Axial mode vibrations may be preferred, because they are likely to cause vibrations that are normal from the surfaces 124S1 and 124S2 of terminal lens 124, thereby providing a greater likelihood of dislodging certain contaminants (e.g., dust, water) from surface 124S2. Frequency ranges of the various mode types may overlap. For example, higher order radial modal frequencies will overlap with the axial modal frequencies, and higher order axial modal frequencies will overlap with wall modal frequencies. However, in practice, this behavior is not an issue because the excitation amplitude and frequency of the transducer will be chosen to yield the desired mode shape in the terminal lens 124 for cleaning. Further, excitation amplitudes and frequencies may be applied to transmit both standing and traveling waves, either in sequential or concurrent fashion, into the desirably chosen circular membrane shape of the terminal lens 124, as further described in the above-described and incorporated U.S. Patent Application Publication No. 2018/0031826.

System 100 provides various improvements over an alternative approach that forms an enclosure around an existing camera system that has its own lenses. In system 100, at least the inner perimeter (e.g., diameter) of housing 106 can be reduced to (or near to) the outer diameter of lenses 108 through 114, and the tolerance between lenses can be ±10 μm. Such tolerance may be ten times greater than tolerance of a system that envelopes a separate (e.g., standalone or off-the-shelf) camera subsystem. Thus, system 100 (including its form factor and the material(s) to construct it) has advantages over a system that envelopes a separate, standalone camera subsystem. Also, system 100 and other actuator/target member systems can perform with greater efficiency by a preferred method of selecting resonance-determining attributes of the actuator (e.g., 120) and the target member (e.g., terminal lens 124), as further described below.

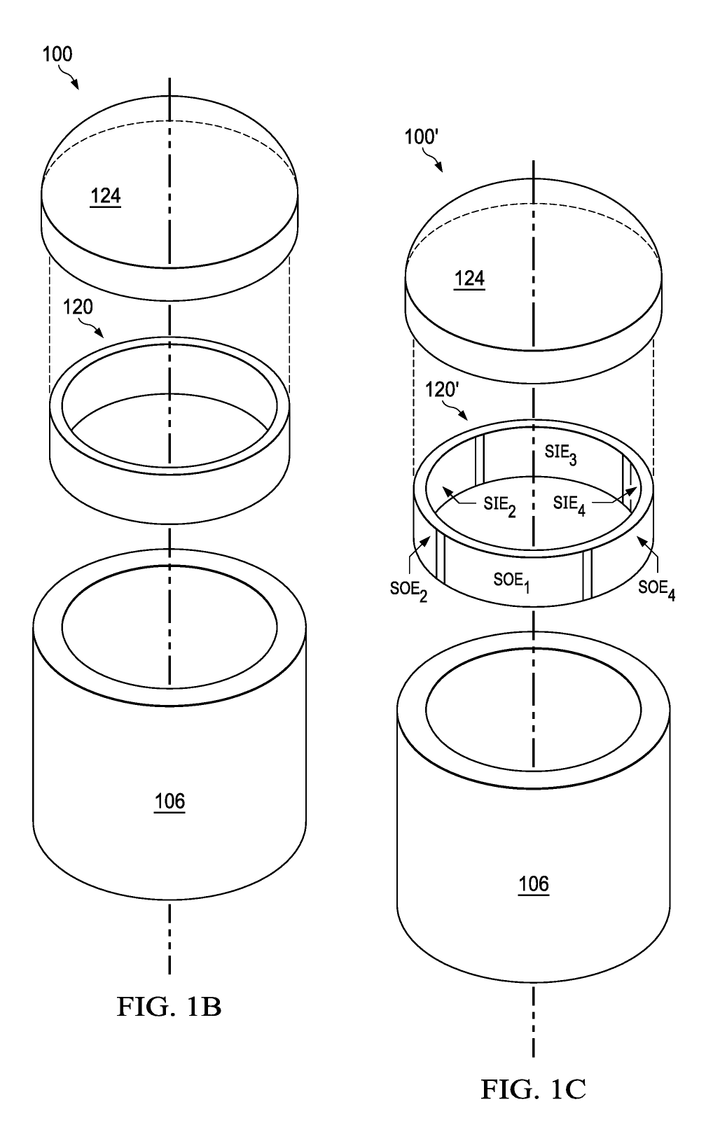

FIG. 2 illustrates an example method 200 of designing and constructing a system such as system 100, which has a vibrational actuator and a target member responsive thereto. Method 200 includes steps for matching the resonant frequencies of both the actuator and the target member, so they resonate at (or within a frequency threshold FTHR (e.g., ±10%) of) a same target frequency (TF) that is suitable for the particular application. Accordingly, in the example described above, such a TF is expected to dispel undesirable material from surface 124S2 of terminal lens 124. Thus, where the TF is desired for terminal lens 124, method 200 determines the physical attributes of terminal lens 124 and of actuator 120, so that each physical device has a structural resonant frequency within threshold FTHR of TF, thereby aligning the resonant behavior of the actuator and the target member.

Method 200 starts with a step 202, which determines the TF for the system application. Accordingly, for system 100 in the example application described above, such a TF is expected to dispel undesirable material from surface 124S2 of terminal lens 124, such as approximately 44 kHz to 2 MHz. Accordingly, in this example embodiment, a frequency in that range is selected, so method 200 then endeavors to match actuator/target member resonant behavior to that frequency. Next, method 200 continues from step 202 to step 204.

Step 204 selects materials, dimensions and/or shape of the target member, so it will naturally resonate at (or within the threshold FTHR of) the TF. In the example of system 100, the target member is terminal lens 124, so the step 204 considers and/or determines the material, shape and dimensions of that lens to naturally resonate at the TF. In a less complex example, if terminal lens 124 is formed as a flat lens, instead of as a fisheye shape, then the flat lens has a uniform thickness and is circular in its outer perimeter. The application itself may dictate a general desired size (e.g., radius of 10 to 12.5 mm) and material (e.g., glass) in such an instance. In that case, the following Equation (1) is useful to perform tradeoff analysis between the glass material, the glass dimensions, and a structural resonance that is at or near the TF.

fᵢⱼ=λᵢⱼ²/2πr²\sqrt{Et³/12γ(1−ν²)} Equation (1)

where,

fᵢⱼ is the resonant frequency for the ith nodal diameter and the jth nodal circle, (Hz);

λᵢⱼ is the eigenvalue for the ith nodal diameter and the jth nodal circle, (unitless);

r is the radius of the terminal lens, (m);

E is modulus of elasticity for the terminal lens material, (N/m²);

t is the thickness of the terminal, (m);

γ is the mass per unit area of the terminal lens material, (kg/m²); and

ν is Poisson's ratio for the terminal lens material, (unitless).

As an example of applying Equation (1), if a TF of 1150 kHz is desired, then Equation (1) is applied to quartz glass and a radius of 10 mm, so a thickness of 0.89 mm gives a resonant frequency of 1150 kHz, which is the resonant frequency of the resultant lens. Thus, if a TF at (or near) 1150 kHz is desired for system 100 (with the alternatively proposed lens as described hereinabove), then actuator 120 be excited to produce vibrations at that TF, and lens 124 will therefore also naturally resonate at that same delivered excitation. Next, method 200 continues from step 204 to step 206.

Step 206 selects materials and/or dimensions of the actuator, so it will likewise have a resonant frequency at (or within the threshold FTHR of) the TF. Thus, continuing the same example, if actuator 120 is to receive an electrical excitation to vibrate at a TF of 1150 kHz, then step 206 considers the material, shape and dimensions of the actuator 120, so its resonant frequency is also the TF. Accordingly, for a given piezo-electric material and the shape of transducer 120 in FIGS. 1A-1C (i.e., hollow cylinder), the frequency constants for the material are determined. For example, the following Table 1 contains the frequency constants for 880 piezo-electric material from American Piezo Company (APC).

TABLE 1
Frequency Constants for Piezo-Electric Material (880)

| Frequency Constant | Value (Hz · m) | Mode |
|---|---|---|
| N_{L} | 1725 | Longitudinal |
| N_{T} | 2110 | Thickness |
| N_{R} | 2120 | Radial |

Per Table 1, to achieve the desired 1150 kHz structural resonant frequency, the cylinder wall of transducer 120 (i.e., the actuator) should be 1.8 mm thick according to the following Equation (2):

N_{T}=fₜ·t Equation (2)

where fₜ is the resonant frequency of the thickness mode.

The diameter and length dimensions can also be used to match other resonant modes if desired. Step 206 also may contemplate more than a singular structure. For example, in the example of system 100 (FIGS. 1A through 1C), step 206 can be applied to transducer 120 alone, or a boundary condition may be expanded to include one or more additional structure(s) coupled to transducer 120, such as lens housing 106 and/or lens retainer member 126. In such a case, the materials/dimensions/shape of the combination of those structures is considered in providing a resonant frequency of the combined structure to match (or be within the threshold FTHR of) a resonant frequency of the target member (i.e., lens 124 in that example). Next, method 200 continues from step 206 to step 208.

Step 208 couples the target member and actuator in fixed position relative to one another. For example, such a fixed relationship is illustrated in FIGS. 1A through 1C, in which actuator 120 either directly physical touches terminal lens 124 or has a fixed relationship to terminal lens 124 via an interim structure and/or adhesive (not shown). This physical coupling, by direct or indirect affixation, allows the mechanical vibration of the actuator to transmit into the target member. Advantageously, because method 200 endeavors to match resonant frequencies of both structures at the TF, the system gain (in the frequency domain) is mathematically the product of respective gains achieved by each independent structure. Thus, for a given amount of energy imparted to a non-resonant matching transducer, a certain positional velocity may be achieved in a target member. But for considerably larger gain (i.e., more force level directed at displacement) with little or no additional energy needed, a multiplicative effect is achieved by example embodiments that match (or align within the frequency threshold FTHR) the resonant frequencies and directionally aligned mode shapes of the actuator and target member. Accordingly, by matching (or aligning within the frequency threshold FTHR) the resonant frequencies and directionally aligned mode shapes, instead of requiring additional energy input to the system, example embodiments greatly enhance operational efficiency (e.g., with reduced power consumption, as compared to achieving the same vibrational energy without such matched resonance). Thus, the combined structure of both the actuator and the target member also has a resonant frequency at or near the TF. Accordingly, instead of selecting a transducer that is merely operable to transmit a desired mechanical force, example embodiments optimize the resultant target member's mechanical force by altering one or more parameters of the actuator (e.g., shape, dimension, material) and likewise of the target member, so as to achieve the advancement in response and result.

Method 200 illustrates a sequential design/selection/formation, but other applications may require the actuator and the target member to be designed simultaneously and not sequentially. In this situation, the dimensions of each component are changed until the matching resonant frequency and mode shape objectives are met. In other situations, the dimensions of the actuator are designed before the dimensions of the target member are designed. After the actuator and target member designs are complete, they are built and attached together to improve the amplitude of vibration in the target member. In some systems, the actuator and target member are glued together. In other systems, they may be mechanically attached using a pressed ring or using screws. Further, because of the increase in vibration amplitude by resonant matching the actuator and target member, tradeoffs can be made to optimize the system. For example, the reference voltage for the actuator can be reduced to improve efficiency, while still maintaining an acceptable level of vibration to meet the system requirements.

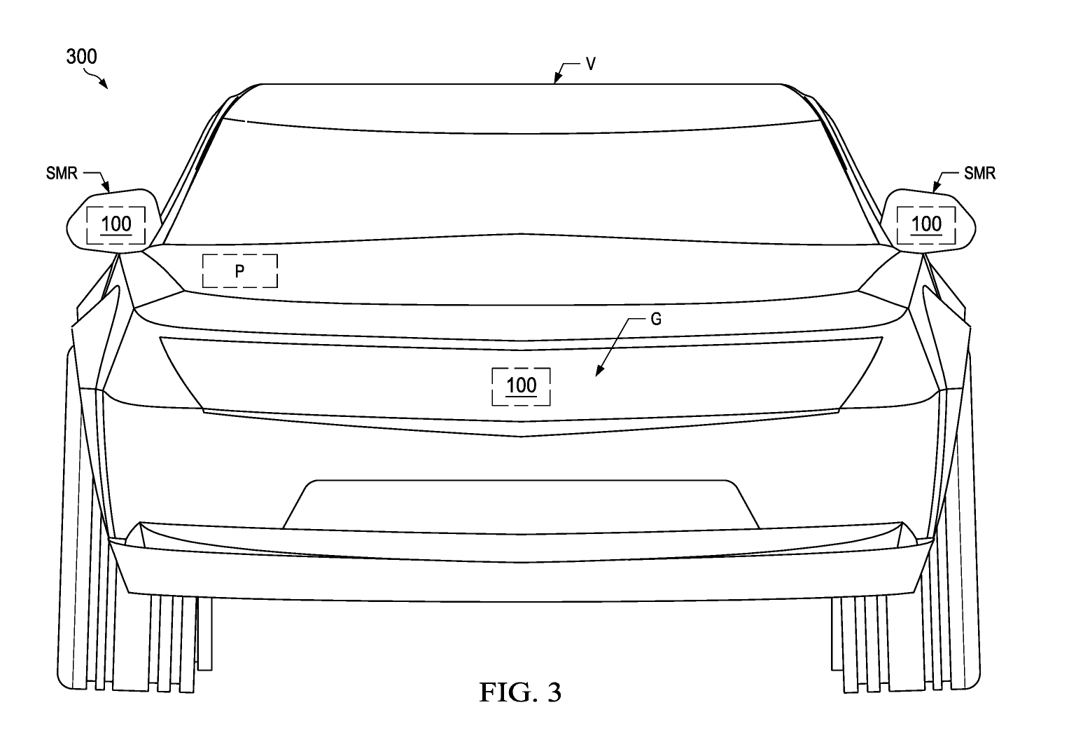

FIG. 3 illustrates an example system 300 with system 100 implemented in numerous locations upon a vehicle V. For example, a forward facing camera may be installed as part of a system 100, in a mount located behind the grill G of vehicle V. As another example, a respective rearward facing camera may be installed as part of a system 100 in each of the vehicle side mirror locations SMR, either in addition to or instead of an actual side mirror. As a further example, another rearward facing camera may be installed near or at the rear of the vehicle V, so as to assist with backup technology. Each system 100 communicates with a processor P (such as a microprocessor, controller, microcontroller, digital signal processor or the like), which is located either under the hood or inside the interior of the vehicle, where such communication may be connected by some type of conductors (such as a vehicle network system). In any event, each system 100 is operable to capture light and provide respective image signals for various types of processing and/or display. Moreover, as described above, each such camera has a lens structure (e.g., lens, lens cover) and associated transducer, which is operable to impart vibrational forces to the lens structure to reduce any contaminants on the surface of the lens structure.

As described above, example embodiments include an improved system with an actuator and target member. In some example embodiments, the system may be an ultrasound lens cleaner, either as a standalone unit or as part of a larger system (e.g., vehicle, surveillance camera, lighting system). In these or other example embodiments, parameters of both the actuator and target member are selected to have a resonant frequency at (or near) the system target frequency, individually and also when coupled to one another. Likewise, such aspects may be implemented in other systems having transducers and target members, such as flow meters, underwater communication devices, imaging systems using sound waves (e.g., ultrasound/ultrasonic, supersonic, megasonic), and others. Such embodiments achieve numerous benefits, such as greater and/or more efficient vibration coverage of the target member.

Modifications are possible in the described embodiments, and other embodiments are possible, within the scope of the claims.

What is claimed is:

1. A lens structure system, comprising:
a housing;
a plurality of lenses supported by an interior of the housing;
a terminal lens coupled to an opening of the housing;
a single-segment transducer coupled to the housing and to the terminal lens;
a photodetector, positioned to receive light through the plurality of lenses and the terminal lens, for generating image signaling in response to the received light; and
circuitry to apply a voltage to the transducer for imparting a vibrational force to the terminal lens.

2. The system of claim 1, wherein imparting the vibrational force comprises imparting standing wave patterns.

3. The system of claim 1, wherein the terminal lens has a resonant frequency within 10 percent of a predetermined frequency, and frequency of the vibrational force is the predetermined frequency.

4. The system of claim 1, wherein the transducer has a resonant frequency within 10 percent of a predetermined frequency, and frequency of the vibrational force is the predetermined frequency.

5. The system of claim 1, wherein the terminal lens comprises a fisheye lens.

6. The system of claim 5, wherein the terminal lens and the plurality of lenses comprise a focusing lens stack through which the light passes.

7. The system of claim 1, wherein the terminal lens comprises a flat lens.

8. The system of claim 1, wherein the terminal lens has a resonant frequency within 10 percent of a predetermined frequency, and the transducer has a resonant frequency within 10 percent of the predetermined frequency.

9. The system of claim 8, wherein frequency of the vibrational force is the predetermined frequency.

10. The system of claim 1, further comprising an adhesive coupling the transducer to the terminal lens.

11. The system of claim 1, wherein the transducer physically abuts at least a portion of the terminal lens.

12. The system of claim 1, wherein in response to the vibrational force, a mode shape of the transducer is directionally aligned with a mode shape of the terminal lens.

13. A lens structure system, comprising:
a housing;
a plurality of lenses supported within an interior of the housing;
a terminal fisheye lens coupled to an opening of the housing, and having a light receiving portion extending beyond the opening;
a transducer coupled to the housing and to the terminal fisheye lens;
a photodetector, positioned to receive light through the plurality of lenses and the terminal fisheye lens, for generating image signaling in response to the received light; and
circuitry to apply a voltage to the transducer for imparting a vibrational force to the terminal fisheye lens.

14. The system of claim 13, wherein the transducer comprises a plurality of segments, and the circuitry comprises circuitry to apply the voltage to selected ones of the segments.

15. The system of claim 14, wherein imparting the vibrational force comprises imparting standing wave patterns.

16. The system of claim 14, wherein imparting the vibrational force comprises imparting traveling wave patterns.

17. The system of claim 13, wherein the transducer is a single-segment transducer.

18. The system of claim 17, wherein imparting the vibrational force comprises imparting standing wave patterns.

19. The system of claim 13, wherein the terminal fisheye lens has a natural resonant frequency within 10 percent of a predetermined frequency, and frequency of the vibrational force is the predetermined frequency.

20. The system of claim 13, wherein the transducer has a natural resonant frequency within 10 percent of the predetermined frequency, and frequency of the vibrational force is the predetermined frequency.

21. The system of claim 13, wherein the terminal fisheye lens has a natural resonant frequency within 10 percent of a predetermined frequency, and the transducer has a natural resonant frequency within 10 percent of the predetermined frequency.

22. The system of claim 21, wherein frequency of the vibrational force is the predetermined frequency.

23. The system of claim 13, further comprising an adhesive coupling the transducer to the terminal fisheye lens.

24. The system of claim 13, wherein the transducer physically abuts at least a portion of the terminal fisheye lens.

25. The system of claim 13, wherein in response to the vibrational force, a mode shape of the transducer is directionally aligned with a mode shape of the terminal fisheye lens.

26. An oscillatory system, comprising:
a target member having a resonant frequency within 10 percent of a predetermined frequency;
a transducer, coupled to the target member, and having a resonant frequency within 10 percent of the predetermined frequency; and
circuitry to apply a voltage to the transducer for imparting a vibrational force to the target member.

27. The system of claim 26, further comprising a housing coupled to the transducer.

28. The system of claim 27, wherein the target member is coupled to the housing.

29. The system of claim 26, wherein the target member comprises a lens.

30. The system of claim 26, wherein the target member comprises an underwater communication apparatus.

31. The system of claim 26, wherein the target member comprises a flow meter apparatus.

32. The system of claim 26, wherein the target member comprises an imaging apparatus.

33. The system of claim 26, wherein the target member comprises an ultrasonic imaging apparatus.

34. The system of claim 26, wherein the target member comprises a megasonic imaging apparatus.

35. The system of claim 26, wherein the target member comprises a supersonic imaging apparatus.

36. The system of claim 26, wherein in response to the vibrational force, a mode shape of the transducer is directionally aligned with a mode shape of the target member.

37. The system of claim 26, wherein at least one of a material, a dimension or a shape of the target member corresponds to the resonant frequency of the target member.

38. The system of claim 37, wherein at least one of a material, a dimension or a shape of the transducer corresponds to the resonant frequency of the transducer.
